(19) United States
(12) Patent Application Publication
(10) Pub. No.: US 2026/0114058 A1
(43) Pub. Date: Apr. 23, 2026

(54) IMAGE SENSOR AND METHOD OF MANUFACTURING IMAGE SENSOR

(71) Applicant: OMNIVISION TECHNOLOGIES, INC., Santa Clara, CA (US)

(72) Inventor: Osamu Fujii, Yokohama (JP)

(73) Assignee: OMNIVISION TECHNOLOGIES, INC., Santa Clara, CA (US)

(21) Appl. No.: 18/924,968

(22) Filed: Oct. 23, 2024

(51) Int. Cl. H01L 27/146

(52) U.S. Cl. CPC H10F 39/80373; H10F 39/014

(57) ABSTRACT

An image sensor includes a semiconductor substrate, a photoelectric conversion region, a semiconductor projecting section, a floating diffusion region, and a transfer gate. The photoelectric conversion region is formed in the semiconductor substrate, the photoelectric conversion region generating electric charges according to incident light. The semiconductor projecting section projects from the semiconductor substrate and extends upward above the photoelectric conversion region. The floating diffusion is provided on a distal end side of the semiconductor projecting section, and the transfer gate is formed to surround the semiconductor projecting section. The image sensor controls, with the transfer gate, an electric field to the semiconductor projecting section to control transfer of the electric charges from the photoelectric conversion region to the floating diffusion.

### TECHNICAL FIELD

The present disclosure relates to an image sensor including a photodiode and a floating diffusion.

### BACKGROUND

In general, an image sensor includes a plurality of pixels arranged in a matrix and generates optical signals from the pixels to obtain a two-dimensional image signal. Therefore, in the pixels, photoelectric conversion elements that generate electric charges according to incident light are provided and circuits for outputting signals generated by the photoelectric conversion elements are provided.

Each pixel can take the following configuration. A photodiode is used as the photoelectric conversion element. Electric charges generated by the photodiode are once accumulated in a floating diffusion via a transfer transistor. A voltage signal of the floating diffusion is supplied to a gate of a source follower transistor. A signal from the source follower transistor is output to an output line via a selection transistor.

The photodiode and the floating diffusion are planarly formed a predetermined distance apart from each other on a semiconductor substrate. An area between the photodiode and the floating diffusion forms a channel area of the transfer transistor. A transfer gate is formed on the semiconductor substrate of the channel area via a gate insulating film. When the photodiode accumulates electrons, the transfer transistor should be an n-channel transistor. When the n-channel transistor is turned off, a negative bias is applied to the transfer gate.

When a large negative bias (for example, −1.4 V) is applied to the transfer gate, a GIDL (Gate Induced Drain Leakage) current is easily generated as a leak current according to a high electric field of transfer gate edges (close contact sections with the floating diffusion). The GIDL current is a noise source. Therefore, in order to improve pixel characteristics, there is a request to reduce the GIDL current.

In order to reduce the GIDL current, it is desirable to move floating diffusion (FD) regions away from transfer gate ends. However, because of pixel refinement in recent years, there is a problem in that there is no margin in pixel regions.

US2022/0005846A1 discloses a pixel circuit including a photodiode and a floating diffusion.

### SUMMARY

An image sensor according to the present disclosure includes: a semiconductor substrate; a photoelectric conversion region formed on an inside of the semiconductor substrate, the photoelectric conversion region generating electric charges according to incident light; a semiconductor projecting section projecting from the semiconductor substrate and extending upward above the photoelectric conversion region; a floating diffusion provided on a distal end side of the semiconductor projecting section; and a transfer gate formed to surround the semiconductor projecting section. The image sensor controls, with the transfer gate, an electric field to the semiconductor projecting section to control transfer of the electric charges from the photoelectric conversion region to the floating diffusion.

With the image sensor of the present disclosure, it is possible to provide an interval in the vertical direction between the transfer gate and the floating diffusion. Therefore, it is possible to extend the interval between the transfer gate and the floating diffusion without increasing a pixel area.

### BRIEF DESCRIPTION OF DRAWINGS

An embodiment of the present disclosure will be described based on the following figures, wherein:

FIG. 1 is a schematic diagram illustrating a circuit configuration of one pixel of an image sensor in accordance with the teachings of the present disclosure;

FIG. 2A is a schematic plan view illustrating a configuration of the one pixel in accordance with the teachings of the present disclosure;

FIG. 2B is a schematic plan view sectional view an A-A line of FIG. 2A and is a schematic diagram illustrating only an upper part of a pixel of FIG. 2A;

FIG. 3 is a schematic diagram illustrating upper part of a floating diffusion region and a transfer gate in accordance with the teachings of the present disclosure;

FIG. 4 is a schematic diagram illustrating an exemplary configuration of transistors provided in the pixel in accordance with the teachings of the present disclosure;

FIG. 5A is a schematic diagram illustrating an example in which an overflow path is additionally formed in the floating diffusion region in accordance with the teachings of the present disclosure;

FIG. 5B is a schematic diagram illustrating an example in which the overflow path is additionally formed in the floating diffusion region in accordance with the teachings of the present disclosure;

FIG. 6A to FIG. 6E are schematic diagrams illustrating a manufacturing processing for a pixel according to an embodiment of the present disclosure;

FIG. 7A illustrates an embodiment in which a photodiode and the transfer gate are divided into four sub groups in accordance with the teachings of the present disclosure;

FIG. 7B illustrates an embodiment in which the photodiode and the transfer gate are divided into four sub groups in accordance with the teachings of the present disclosure;

FIG. 8 is a schematic diagram illustrating a configuration of a pixel in a pipe-like channel area modification in accordance with the teachings of the present disclosure;

FIG. 9A illustrates a part of a process for manufacturing the pixel illustrated in FIG. 7A and FIG. 7B in accordance with the teachings of the present disclosure; and

FIG. 9B illustrates a part of a process for manufacturing the pixel illustrated in FIG. 7A and FIG. 7B in accordance with the teachings of the present disclosure.

### DESCRIPTION OF EMBODIMENT

In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects. Note that the embodiment explained below does not limit the present disclosure. A configuration formed by selectively combining a plurality of illustrations is also included in the present disclosure.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

### “Circuit Configuration”

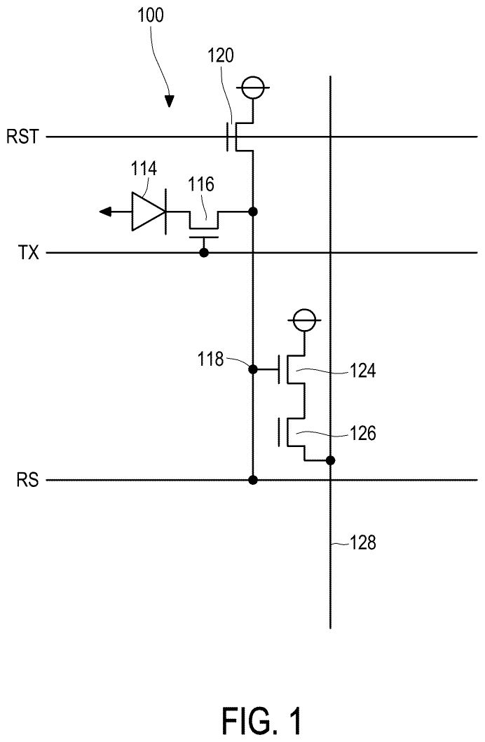

FIG. 1 illustrates a circuit configuration of one pixel of an image sensor in accordance with the teachings of the present disclosure. In this example, a photodiode 114 is provided in each pixel. The photodiode 114 is configured to photo-generate electric charges (e.g., electrons or holes) in response to an incident light. The photodiode 114 is coupled to a floating diffusion region 118 having a predetermined capacitance via a transfer transistor 116. The floating diffusion region 118 accumulates electric charges transferred from the photodiode 114. A gate of a source follower transistor 124 is coupled to the floating diffusion region 118. A drain electrode of the source follower transistor 124 is coupled to a power supply. A source electrode of the source follower transistor 124 is coupled to a drain electrode of a row selection transistor 126.

A gate electrode of the row selection transistor 126 is coupled to a row selection line RS. A source of the row selection transistor 126 is coupled to a bit line 128, which is an output line in a column direction.

A gate electrode of a reset transistor 120 is connected to a reset line RST. A drain electrode of the reset transistor 120 is connected to the power supply. A source electrode of the reset transistor 120 is connected to a source electrode of the transfer transistor 116.

Referring to FIG. 1, firstly, a reset line RST is changed into an H level (H: high level), whereby the reset transistor 120 is turned on and the floating diffusion region 118 is reset. Consequently, the source follower transistor 124 is also reset.

Subsequently, the reset line RST returns to a L level (L: low level). Thereafter, after a predetermined exposure time elapses, a transfer control line TXL is turned on. Consequently, the transfer transistor 116 is turned on. The photo-generated electric charges accumulated in the photodiode 114 are transferred to the floating diffusion region 118. When the row selection line RS is changed to an H level, which turns on the row selection transistor 126, accumulated electric charges in floating diffusion region 118 is read out to the bit line 128 as an image signal via the row selection transistor 126.

In some other embodiments, the image sensor may include a control circuit (not illustrated) coupled to the pixel. The control circuit may be configured to set voltage signal on the reset line RST, the transfer control line TXL, and the row selection line RS, so as to control an operation (e.g., a reset or a pre-charge operation, an exposure operation, an charge transfer operation, and the like) of the pixel.

### “Element Configuration”

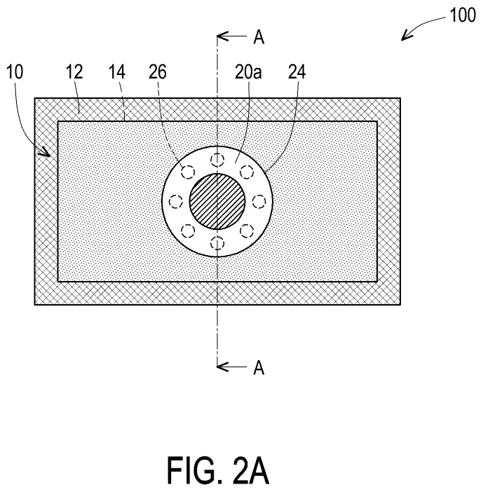

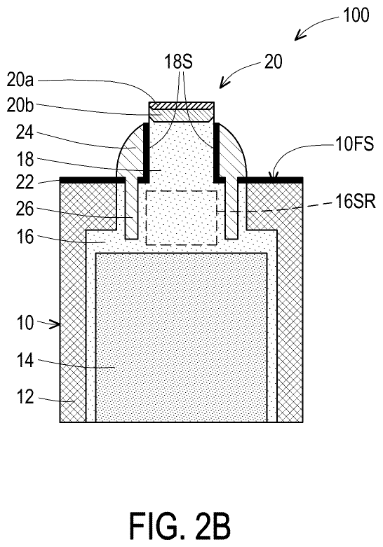

FIG. 2A is a plan view illustrating an exemplary configuration of one pixel 100 in accordance with the teachings of the present disclosure. FIG. 2B is a sectional view along an A-A line of FIG. 2A and illustrates only an upper part of the pixel 100. It should be noted that the view presented in FIG. 2A and FIG. 2B may omit certain elements of pixel 100 to avoid obscuring details of the disclosure. A plurality of the pixels 100 are disposed in a matrix on a semiconductor substrate 10.

It should be noted that the term “semiconductor substrate” recited throughout the disclosure may correspond to a part of or an entirety of a semiconductor wafer (e.g., a silicon wafer). In some embodiments, the semiconductor substrate 10 may include or may be otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof.

The semiconductor substrate 10 may correspond to any semiconductor material or combination of materials that may be doped or otherwise configured to facilitate the formation of an integrated circuit (e.g., forming individual circuitry components such as source/drain regions of transistors, memory elements, photodiodes, or the like).

Referring to FIG. 2A, a region of the pixel 100 may be defined in a square shape in a plan view. A well isolation 12 is disposed in the periphery of the pixel 100 in the semiconductor substrate 10. The well isolation 12 may be a part of the semiconductor substrate 10. The well isolation 12 may be, for example, a P+ doped region with P-type impurities and may extend in the depth direction from the substrate surface of the semiconductor substrate 10. The well isolation 12 may partition the pixel 100 from the other pixels.

A photodiode 14 may be formed or otherwise disposed in the semiconductor substrate 10 of the pixel 100. The photodiode 14 corresponds to a photoelectric conversion region that generates electric charges (e.g., electrons) in accordance with incident light. The photodiode 14 includes a p region (p type impurity doped region) and an n region (n type impurity doped region). In some embodiments, the photodiode 14 may correspond to a doped region disposed within the semiconductor substrate 10 configured to photo-generate image charge in response to the incident light. For example, the photodiode 14 may correspond to an n-doped region disposed within a p-type semiconductor substrate or an n-doped region surrounded by a p-type well (e.g., well isolation 12) disposed within the first semiconductor substrate 10.

Referring to FIG. 2B, a region between the photodiode 14 and the well isolation 12 in the semiconductor substrate 10 is formed as a semiconductor region 16. The semiconductor region 16 is a part of the semiconductor substrate 10 covering lateral side parts and an upper part of the photodiode 14. The semiconductor region 16 disposed on the upper side of the photodiode 14 further extends to a region above the semiconductor substrate 10 to form a semiconductor projecting section 18. As shown in FIG. 2B, the semiconductor projecting section 18 is formed above the semiconductor substrate 10. The semiconductor projecting section 18 may vertically extend from a substrate surface 10FS (e.g., a front side surface) of the semiconductor substrate 10. In the present embodiment, the semiconductor projecting section 18 is desirably formed to project above the semiconductor substrate 10 by an epitaxial growth process. At least a portion of the semiconductor region 16 (e.g., substrate region 16SR) and the semiconductor projecting section 18 form an area that is functioned as a channel area of the transfer transistor (e.g., exemplarily shown as the transfer transistor 116 in FIG. 1). In the embodiment, the transfer transistor includes a transfer gate 24 and a plurality of vertical transfer gates 26 extended from the transfer gate 24 into the semiconductor substrate 10. In some embodiments, the plurality of vertical transfer gates may be arranged with equal spacing and disposed to surround the substrate region 16SR. In the present embodiment, since an n channel transistor is formed, in general, the area is a p-doped region. However, the area may also be a non-doped (un-doped) or a lightly n-doped region. In the present embodiment, the semiconductor projecting section 18 is in a columnar shape.

As shown in FIG. 2B, a floating diffusion region 20 is formed or otherwise disposed proximately to or at the upper end (i.e., a distal end 18DE) of the semiconductor projecting section 18. In some embodiments, the floating diffusion region 20 is a doped region in the semiconductor projecting section 18. Namely, the floating diffusion region 20 may be a part of the semiconductor projecting section 18. The floating diffusion region 20 is a region doped with n-type impurities and includes a heavily doped region 20a and a lightly doped region 20b. The lightly doped region 20b has a concentration less than that of the heavily doped region 20a. In some embodiments, the heavily doped region 20a is formed within the lightly doped region 20b. In some embodiments, the heavily doped region 20a may be considered as an upper portion of the floating diffusion region 20, and a lightly doped region 20b may be considered as a lower portion of the floating diffusion region 20. In some embodiments, the lightly doped region 20b is immediately adjacent to the floating diffusion region 20.

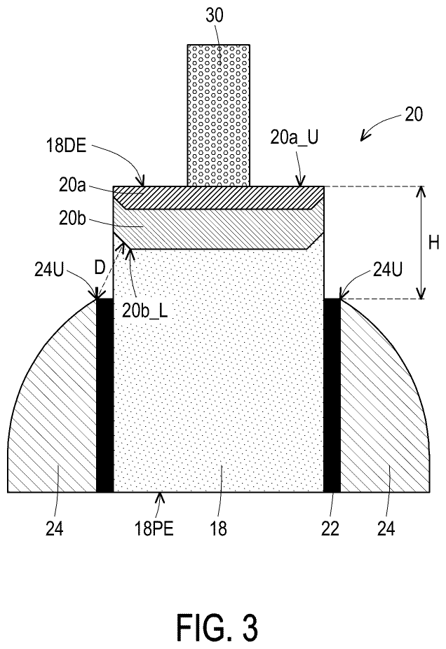

FIG. 3 is a diagram illustrating an upper part of a floating diffusion region 20 and the transfer gate 24 in accordance with the teachings of the present disclosure. In some embodiments, a distance between a proximal end 18PE of the semiconductor projecting section 18 and the lightly doped region 20b is less than a distance between the proximal end 18 PE of the semiconductor projecting section 18 and a heavily doped region 20a. As shown in FIG. 3 the proximal end 18PE of the semiconductor projecting section 18 is opposite to the distal end 18DE. The proximal end 18PE of the semiconductor projecting section 18 refers to an end of semiconductor projecting section 18 closer to a substrate surface 19FS (e.g., a front side surface) of the semiconductor substrate 10.

Referring again to FIG. 3, an insulating film 22 is formed to cover the surface of the semiconductor substrate 10 and side surfaces 18S of the semiconductor projecting section 18. The insulating film 22, an oxide film, for example, a silicon oxide film may be used. The transfer gate 24 is formed on the surface (e.g., a part of substrate surface 10FS) of the semiconductor region 16 of the semiconductor substrate 10 and the lateral side surfaces of the semiconductor projecting section 18. The insulating film 22 is disposed between the transfer gate 24 and the semiconductor region 16. That is, the insulating film 22 can be functioned as a gate insulating film. The transfer gate 24 may be in an annular shape, gradually decreases in thickness toward the direction of the floating diffusion region 20, and is terminated at a predetermined distance (e.g., distance D illustrated in FIG. 3) apart from the floating diffusion region 20. Namely, the lateral side surfaces of the semiconductor projecting section 18 are interposed by a predetermined length between the lower end of the lightly doped region 20b of the floating diffusion region 20 and the upper end of the transfer gate 24. In the present embodiment, the transfer gate 24 is formed of, for example, polysilicon doped with impurities. In some embodiments, the transfer gate 24 may include a top gate electrode disposed on the semiconductor substrate 10. The top gate electrode may be disposed proximately to the semiconductor projecting section 18 and from which one or more vertical transfer gate electrodes extending into the semiconductor substrate 10.

Referring again to FIG. 2A and FIG. 2B, in the illustrated embodiments, multiple vertical transfer gates 26 extend downward from a portion of top gate electrode of the transfer gate 24 adjacent to an upper part of the semiconductor region 16. In the present embodiment, eight vertical transfer gates 26 may be formed in the pixel 100. As shown in FIG. 2A, in the present embodiment, the eight vertical transfer gates 26 may be equally spaced apart from each other. Each of the vertical transfer gates 26 may be disposed proximately to the photodiode 14. For example, each of the vertical transfer gates 26 may be formed in a manner of being terminated above the upper end of the photodiode 14. That is, the semiconductor region 16 having a predetermined length is interposed between the lower ends of the vertical transfer gates 26 and the upper end of the photodiode 14. In the present embodiment, the transfer gate 24 and the plurality of vertical transfer gates 26 can be configured to couple the photodiode 14 to the floating diffusion region 20.

In such a configuration, referring to FIG. 2B, at least part of the semiconductor region 16 (e.g., the substrate region 16SR) and the semiconductor projecting section 18 are disposed between the upper end of the photodiode 14 and the floating diffusion region 20. At least a part of the semiconductor region 16 (e.g., the substrate region 16SR) and the corresponding region of the semiconductor projecting section 18 function as a channel area (or channel region) that is operated in accordance with electric fields applied from the transfer gate 24 and the vertical transfer gates 26. That is, a positive voltage is applied to the transfer gate 24 and the vertical transfer gates 26, whereby the channel area changes to an n type or a depletion layer, and thus charges (e.g., electrons) move from the photodiode 14 to the floating diffusion region 20. Therefore, in an exemplary embodiment, the area of at least a part of the semiconductor region 16 (e.g., the substrate region 16SR) and the corresponding region of the semiconductor projecting section 18 disposed between the photodiode 14 and the floating diffusion region 20 may correspond to a channel region for the transfer transistor 116 illustrated in FIG. 1.

As shown in FIG. 3, the upper parts of the floating diffusion region 20 and the transfer gate 24 are illustrated. It is noted that, in FIG. 3, a contact 30 coupled to the floating diffusion region 20 is illustrated. In some embodiments, the contact 30 may be made of conductive materials. In some other embodiments, the contact 30 may be made of metallic materials such as tungsten but may be made of polysilicon or the like. The contact 30 may couple the floating diffusion region 20 to other pixel elements such as source follower through one or more metal interconnect (not illustrated herein).

Referring again to FIG. 3, in the present embodiment, the distance H between the upper end 24U of the transfer gate 24 and the upper end (e.g., the upper end 20a_U of the heavily doped region 20a) of the floating diffusion region 20 is set to be approximately from 100 nm to 400 nm. The distance D between the lightly doped region 20b on the lower side of the floating diffusion region 20 (e.g., the lower end of floating diffusion region 20) and the upper end 24U of the transfer gate 24 is set to be approximately 80 nm. A GIDL current can be suppressed in such fashion by setting the distance between the upper end of the transfer gate 24 and the floating diffusion region 20 to be a predetermined distance or more. The above distance is substantially a distance in the vertical direction along an extending direction of the semiconductor projecting section 18. In the present embodiment, attributable to the above configuration, a pixel area does not need to be increased for enabling pixel minimization. Further, by providing the heavily doped region 20a, it is possible to set electric resistance (contact resistance) of the floating diffusion region 20 and the contact 30 to be in a relatively small resistance. It is worth noting that the impurity concentration of the heavily doped region 20a can be set to be, for example, approximately 1e20 ion/cm³, and the impurity concentration of the lightly doped region 20b can be set to be, for example, approximately 1e18 ion/cm^{3.}

In the present embodiment, the semiconductor projecting section 18 is a monocrystalline or polycrystalline silicon layer or region epitaxially grown from the semiconductor substrate 10. As shown in FIG. 3, the semiconductor projecting section 18 is surrounded by the transfer gate 24. In some embodiments, the semiconductor projecting section 18 has a pipe shape or a pipe-like shape such as a column shape or a prism shape. In some embodiments, the semiconductor projecting section 18 may have a circular cross-sectional shape in a plane (e.g., x-y plane) that is parallel to substrate surface 10FS. The semiconductor projecting section 18 is further separated and isolated from the transfer gate 24 by the insulating film 22.

In the present embodiment, referring to FIG. 2B, the vertical transfer gates 26 are provided. Consequently, it is possible to easily move electric charges from the photodiode 14 to the floating diffusion region 20.

In some embodiments, the transfer gate 24 may not include the vertical transfer gate 26. In the present embodiment, the vertical direction length of the semiconductor region 16 of the photodiode 14 is desirably set to be in a relatively short length. In some embodiments, the transfer gate 24 may include a single vertical transfer gate electrode.

The transfer gate 24 may be disposed proximately to the center at the upper end of the photodiode 14. The transfer gate 24 can be disposed in a region having a voltage close to a pinning voltage (Vpin) of the photodiode 14. Accordingly, electric charge transfer performance (e.g., transfer efficiency and lag reduction) and pixel refinement (≤0.5 μm) can be realized.

It is noted that, in the present embodiment, the heavily doped region 20a and the lightly doped region 20b may be also divided with each other or separately disposed via an implantation process. However, impurity concentration may be sequentially reduced (or gradually reduced) from an upper part toward a lower part of the floating diffusion region 20.

### “Exemplary Configuration of the Transistors”

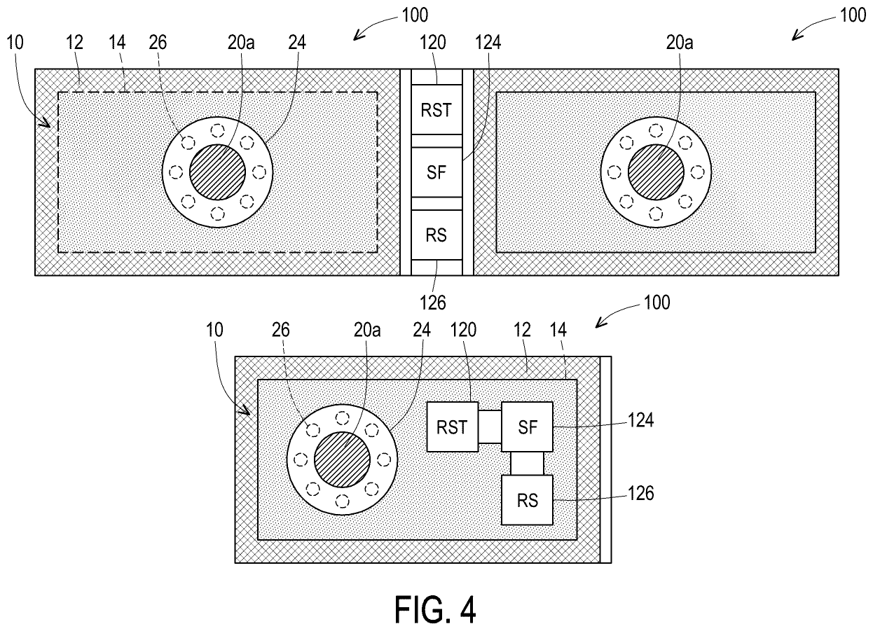

FIG. 4 is a diagram illustrating an exemplary configuration of the transistors provided in the pixel 100 in accordance with the teachings of the present disclosure. In an example illustrated in an upper part of FIG. 4, the pixel transistor such as the reset transistor 120, the source follower transistor 124, and the row selection transistor 126 are disposed on the semiconductor substrate 10. The semiconductor substrate 10 is located on the outer sides of the well isolation 12 and between adjacent pixels. Referring to FIG. 2B and FIG. 4, in an example illustrated in a lower part of FIG. 4, the reset transistor 120, the source follower transistor 124, and the row selection transistor 126 are disposed in the semiconductor region 16. As shown in FIG. 2B and FIG. 4, the semiconductor region 16 is located on the inner sides of the well isolation 12 and beneath the heavily doped region 20a.

In both of the above configurations of the pixel 100, the effects described above can be obtained.

### “Modification: An Overflow Path”

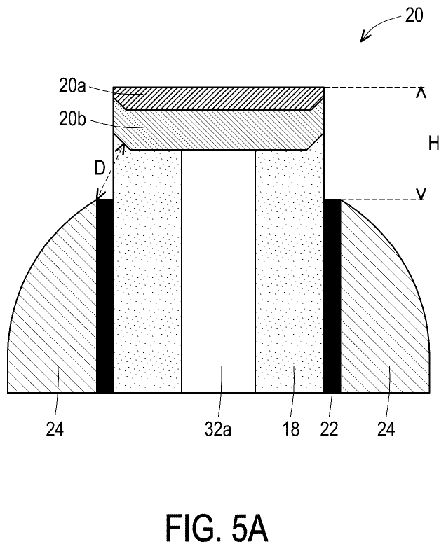

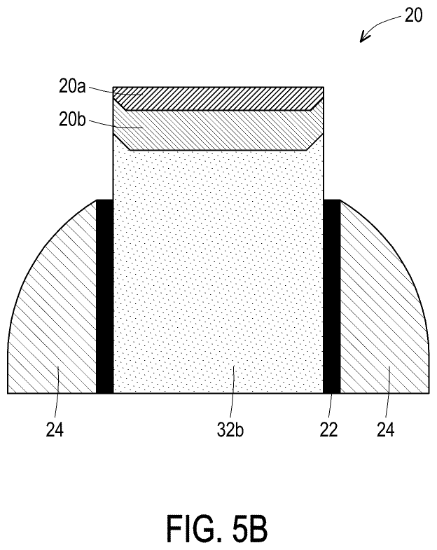

FIGS. 5A and 5B are diagrams illustrating examples in which an overflow path 32 is formed for the floating diffusion region 20 in accordance with the teachings of the present disclosure.

The overflow path 32 is a path for, when electric charges (e.g., electrons) accumulated in the floating diffusion region 20 are in a predetermined amount or more, the electric charges (e.g., the electrons) are overflowed and led out to another place. The overflow path 32 may be a doped region in the semiconductor projecting section 18 formed via an ion implantation process. In some embodiments, the overflow path 32 may be a doped region having a same conductive type as the floating diffusion region 20 and the photodiode 14. The electric charges overflowed from the overflow path 32 may be discarded in a predetermined power supply or may be accumulated in a separately provided capacitor.

It should be noted that the view presented in FIG. 5A and FIG. 5B may omit certain elements of a pixel to avoid obscuring details of the disclosure.

Referring to FIG. 5A, an overflow path 32a is a doped region extending downwardly from the center of the lower end of the lightly doped region 20b of the floating diffusion region 20 toward the photodiode 14. The overflow path 32a with such configuration can be formed by controlling implantation of impurities after the semiconductor projecting section 18 being formed by an epitaxial growth process. The overflow path 32a may have the same conductive type as the floating diffusion region 20.

Referring to FIG. 5B, the semiconductor projecting section 18 disposed on the lower side of the lightly doped region 20b of the floating diffusion region 20 is formed as an overflow path 32b in the lightly doped region 20b. The overflow path 32b with such configuration can be formed by doping impurities at low concentration as the semiconductor projecting section 18 being formed by an epitaxial growth process.

### “Manufacturing Process”

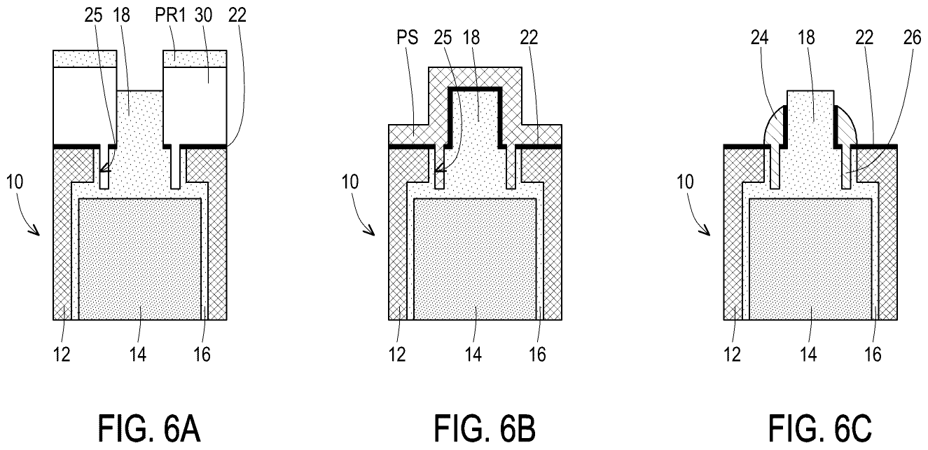

FIG. 6A to FIG. 6E are diagrams illustrating a manufacturing process for a pixel according to an embodiment in accordance with the teachings of the present disclosure.

Referring to FIG. 6A, the semiconductor substrate 10 with the photodiode 14, the well isolation 12, and the insulating film 22 formed thereon is prepared. The preparation process of the semiconductor substrate 10 is a conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is noted that the described techniques are merely demonstrative and not exhaustive and that other techniques may be utilized to fabricate one or more components of various embodiments of the disclosure. Therefore, explanation thereof is omitted.

### (1) Solid-Phase Epitaxial Growth

Referring again to FIG. 6A, firstly, trenches for forming the vertical transfer gates 26 are formed on the semiconductor substrate 10 via photolithography process. Subsequently, a sacrificial material such as a dummy oxide-based material 30 is deposited to a predetermined height and a photoresist PR1 is patterned thereon to form a tubular hole for formation of the semiconductor projecting section 18. In the current formation step, a portion of the insulating film 22 located at the bottom of the tubular hole is removed to expose the semiconductor substrate 10.

As shown in FIG. 6A, an epitaxial region (Epi) is formed by solid-phase epitaxial growth on the semiconductor substrate 10 (in the present embodiment, e.g., a silicon substrate). In the current process step, the epitaxial region Epi is formed to be the semiconductor projecting section 18 made of silicon monocrystal. In some embodiments, the semiconductor projecting section 18 is epitaxially grown such that semiconductor projecting section 18 is structurally connected with the underlying semiconductor substrate 10.

### (2) Polysilicon Deposition

Referring to FIG. 6A and FIG. 6B, the photoresist PR1 and the sacrificial material, the dummy oxide-based material 30 materials, are removed to expose trenches 25 from the semiconductor projecting section 18. The periphery of the semiconductor projecting section 18 formed by the epitaxial growth is further thermally oxidized to form the insulating film 22 on the side surfaces (e.g., side surfaces 18S of FIG. 2B) of the semiconductor projecting section 18 and lateral side surfaces of the vertical gate trenches 25 for forming vertical transfer gates 26. Thereafter, polysilicon material (PS) is deposited, and the impurities are doped in the polysilicon (PS). Consequently, the semiconductor projecting section 18 is covered by the insulating film 22. In such manner, the semiconductor projecting section 18 is separated from the deposited polysilicon material (PS), and semiconductor region 16 surrounding the vertical gate trenches is separated from the deposited polysilicon material (PS) by the insulating film 22. As shown in FIG. 6A to FIG. 6C, the polysilicon material (PS) is filled in the vertical gate trenches 25 for forming the vertical transfer gates 26 that covers a portion of the upper surface of the semiconductor projecting section 18.

### (3) Reactive Ion Etching (RIE)

Referring to FIG. 6B and FIG. 6C, an upper part of the semiconductor projecting section 18 is exposed and a portion of the polysilicon material (PS) apart from the periphery of the semiconductor projecting section 18 is subsequently removed by a reactive ion etching (RIE) process. Consequently, the transfer gate 24 and the vertical transfer gates 26 are formed as shown in FIG. 6C.

### (4) Implantation & Annealing

Referring to FIG. 6D and FIG. 6E, subsequently, a photoresist PR2 is deposited, and an upper surface portion of the semiconductor projecting section 18 is exposed by a patterning process. Further, impurities may be doped through the upper surface of the semiconductor projecting section 18, for example by an implantation process. Thereafter, a dopant is activated by an annealing process to form the floating diffusion region 20 (including the lightly doped region 20b and the heavily doped region 20a). It is noted that As, P, or the like is used as a dopant of an n type region.

### (5) Contact

In the present embodiment, an inter-layer insulating film 50 may be formed to cover the entire semiconductor substrate 10 and the contact 30 with the transfer gate 24. In the current formation step, the heavily doped region 20a of the floating diffusion 20 is formed.

### “Modification: Division of the Photodiode”

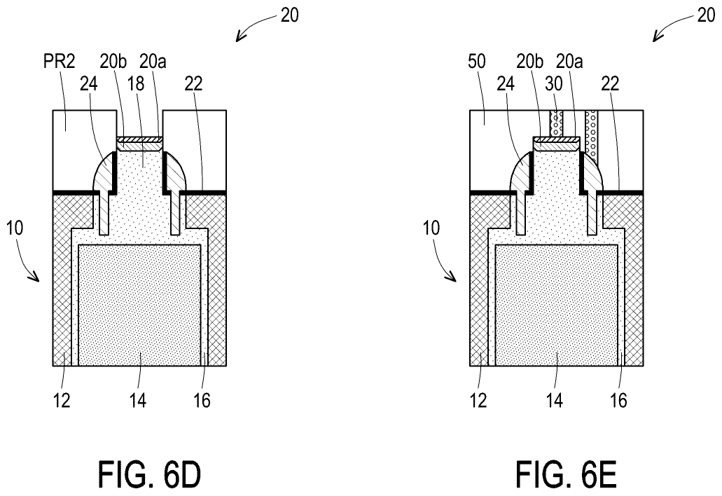

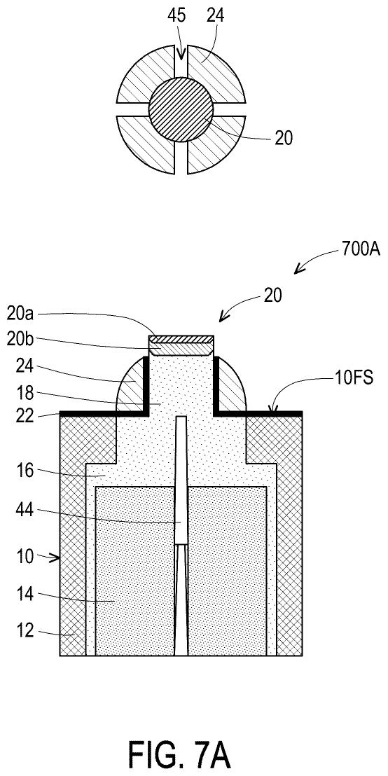

FIG. 7A and FIG. 7B illustrate exemplary embodiments in which the photodiode 14 and the transfer gate 24 are divided into a plurality of (in this example, four) photodiodes and a plurality of (in this example, four) transfer gates in accordance with the teachings of the present disclosure.

In the configuration mentioned above, the photodiode 14 and the transfer gate 24 are divided into four sub structure in a plan view shown in the upper portion of the FIG. 7A. As shown in FIG. 7A and FIG. 7B, the photodiode 14 is divided into four sub-photodiodes by an isolation structure 44, and each two adjacent sub-photodiodes are also isolated from each other by isolation structure 44. The transfer gate 24 is divided into four transfer gates by intervention of interval spaces 45 therebetween. In some other embodiments, the interval spaces 45 or gap between the four transfer gates may be filled with dielectric material, for example, an oxide-based material, a silicon nitride, and the like, to provide isolation between individual transfer gates.

Therefore, by turning on the transfer gate 24 having a quarter size, the accumulated electric charges of each respective photodiode 14 corresponding to the transfer gate 24 can be transferred to the floating diffusion region 20. The accumulated electric charges of each of the four divided photodiodes 14 can be sequentially detected. Hence, information such as autofocus may be obtained.

FIG. 7A illustrates an example in which the vertical transfer gates 26 are not included, for example, transfer gate 24 in FIG. 7A may include only a top gate electrode. FIG. 7B illustrates an example in which the vertical transfer gates 26 are provided. It is noted that an isolation structure 44 can be made of the same material as the material of the well isolation 12. The isolation structure 44 can be formed from both of the front surface direction e.g., extending from the front surface (e.g., the substrate surface 10FS) into the semiconductor substrate 10 toward a rear (or backside) surface thereof and the rear surface direction. For example, the isolation structure 44 may include a trench or junction isolation structure that extend from the front surface (e.g., the substrate surface 10FS) into the semiconductor substrate 10 toward the rear surface thereof and a second trench isolation structure that extend from a rear (or backside) surface of the semiconductor substrate 10 toward the substrate surface 10FS. The second trench isolation structure may extend to be formed on the rear surface of the semiconductor substrate 10, and the trench or junction isolation structure that extends from the front surface (e.g., the substrate surface 10FS) may be in contact with each other.

FIG. 7B further illustrates that the transfer gate 24 and the vertical transfer gates 26 are arranged to be a plurality of individual separated transfer gate structure, where each transfer gate structure couple a corresponding photodiode 14 to the shared floating diffusion region 20.

In an alternative embodiment, a pixel 700A illustrated in FIG. 7A and a pixel 700B illustrated in 7B illustrates an exemplary unit pixel that includes a plurality of photodiodes 14, a plurality of transfer gates 24, and a floating diffusion region 20. The plurality of transfer gates is configured to couple a plurality of photodiodes 14 to the floating diffusion region 20.

### “Modification: Pipe-Like Channel Area”

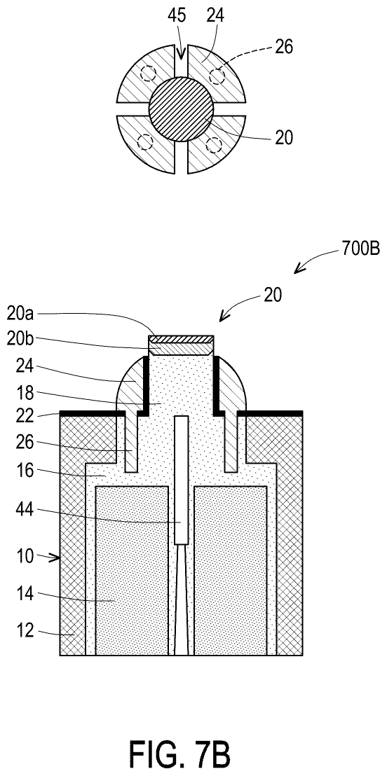

FIG. 8 is a diagram illustrating a configuration of a pixel in a pipe-like channel area modification. As illustrated, a cylindrical-shaped core oxide 40 extending in the up-down direction along a thickness direction of the substrate 10 is formed in the center of the semiconductor projecting section 18 and the floating diffusion region 20. The cylindrical-shaped core oxide 40 is, for example, formed of an oxide silicon and is an insulator core region. Therefore, the semiconductor projecting section 18 may be formed in a pipe-like shape. The pipe-like portion of the semiconductor projecting section 18 may enclose a channel area formed by the transfer gate 24 between the photodiode 14 and the floating diffusion region 20. Even in a configuration in which such a pipe-like channel area is provided, it is still possible to set the interval (or a vertical distance) between the transfer gate 24 and the floating diffusion 20 to a desired interval and thus to effectively suppress occurrence of a leak current.

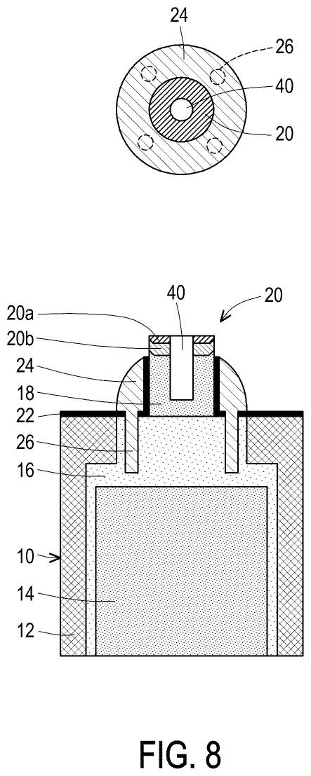

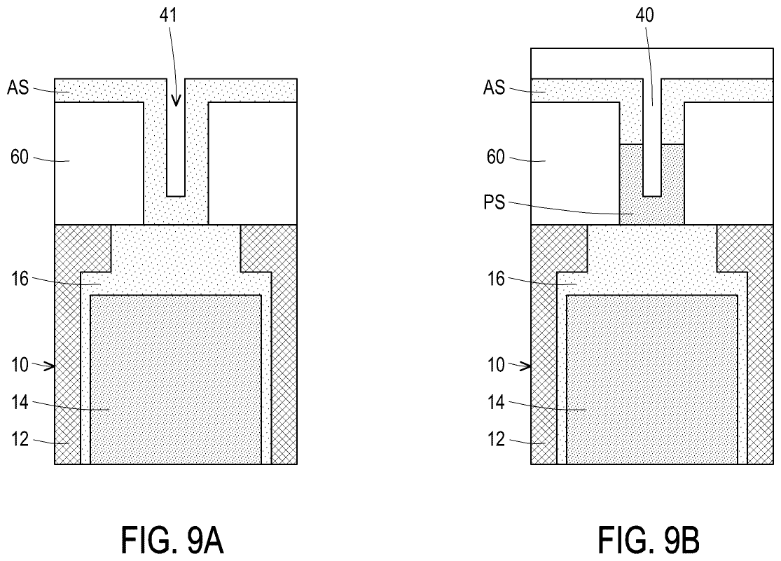

FIGS. 9A and 9B illustrate a part of a process for manufacturing the pixel illustrated in FIG. 8. As illustrated, when the semiconductor projecting section 18 is formed, as shown in FIG. 9A, an amorphous silicon AS is deposited. An area where the amorphous silicon AS is deposited corresponds to the pipe-like channel area. Referring to FIG. 9B, at least a portion of the amorphous silicon AS is changed to polysilicon material PS or monocrystalline silicon by an annealing process. Thereafter, an oxide is filled in a hole 41 located at the center of the amorphous silicon AS to form the core oxide 40 having a cylindrical shape with dimensions defined by the hole 41 or an opening.

Consequently, the pipe-like channel area can be formed under the floating diffusion region 20. In some embodiments, the pipe-like channel area may be surrounded by a dielectric material 60, for example, an oxide-based material.

### “Effects of the Embodiment”

With the image sensor according to this embodiment, it is possible to adjust, in the vertical direction, the distance from the end portion of the transfer gate 24 to the end portion of the floating diffusion region 20. Therefore, it is possible to change the distance without changing a planar pixel layout. Accordingly, it may be easier to set the distance to a proper distance and thus to suppress a leak of an electric current in a position of this distance. Further, the impurity concentration of the floating diffusion 20 may be increased and thus reduce contact resistance with the contact.

Through the above-mentioned configuration, the distance from the end portion of the transfer gate 24 to the end portion of the floating diffusion region 20 may be easily adjusted by changing an epitaxial growth height.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

1. An image sensor comprising:
a semiconductor substrate;
a photoelectric conversion region formed in the semiconductor substrate, wherein the photoelectric conversion region generating electric is configured to charge according to incident light;
a semiconductor projecting section projecting from the semiconductor substrate and extending upward above the photoelectric conversion region;
a floating diffusion region provided on a distal end side of the semiconductor projecting section; and
a transfer gate surrounding the semiconductor projecting section, wherein
the image sensor is configured to control, with the transfer gate, an electric field to the semiconductor projecting section to control transfer of the electric charges from the photoelectric conversion region to the floating diffusion region.

2. The image sensor according to claim 1, wherein
the photoelectric conversion region is located below and separated from a surface of the semiconductor substrate, and
the transfer gate comprises a vertical transfer gate extending vertically toward the semiconductor substrate.

3. The image sensor according to claim 2, wherein the transfer gate comprises a top gate electrode disposed on the surface of the semiconductor substrate and the vertical transfer gate extended from the top gate electrode into the semiconductor substrate.

4. The image sensor according to claim 1, wherein the transfer gate comprises a top gate electrode and a plurality of vertical transfer gates extended from the top gate electrode into the semiconductor substrate, wherein the plurality of vertical transfer gates is disposed to surround a substrate region of the semiconductor substrate.

5. The image sensor according to claim 1, wherein
an upper end of the transfer gate is located below a distal end of the semiconductor projecting section, and
the semiconductor projecting section comprises at least part of channel region of the transfer gate disposed between the upper end of the photodiode and a lower end of the floating diffusion region.

6. The image sensor according to claim 5, wherein the lower end of the floating diffusion region is distanced from the upper end of the transfer gate by a first distance, and an upper end of the floating diffusion region is distanced from the upper end of the transfer gate by a second distance greater from the first distance.

7. The image sensor according to claim 1, wherein
the semiconductor projecting section has a columnar shape, and
the transfer gate has a pipe shape that covers a periphery of the semiconductor projecting section.

8. The image sensor according to claim 1, wherein the floating diffusion region includes a heavily doped region on the distal end side of the semiconductor projecting section and a lightly doped region in the semiconductor projecting section immediate adjacent to the heavily doped region.

9. The image sensor according to claim 1, wherein an insulating film is disposed between the semiconductor projecting section and the transfer gate.

10. The image sensor according to claim 1, wherein the image sensor comprises, in a center of the semiconductor projecting section, an insulator core region extending in an up-down direction of the image sensor and piercing through a center of the floating diffusion region.

11. The image sensor according to claim 1, wherein the image sensor comprises, in a center of the semiconductor projecting section, an impurity-doped overflow path extending in an up-down direction along a thickness direction of the semiconductor substrate.

12. The image sensor according to claim 1, wherein the semiconductor projecting section is impurity-doped and functioned as an overflow path.

13. The image sensor according to claim 1, wherein the photoelectric conversion region comprises a first photoelectric conversion region of a plurality of photoelectric conversion regions included in a pixel of the image sensor,
wherein the transfer gate comprises a first transfer gate of a plurality of transfer gates included in the pixel of the image sensor, wherein each of the plurality of transfer gates is electrically isolated,
wherein the plurality of transfer gates is configured to couple the plurality of photoelectric conversion regions to the floating diffusion region.

14. The image sensor according to claim 13, wherein the plurality of transfer gates is disposed on the semiconductor substrate surrounding the semiconductor projecting section.

15. The image sensor according to claim 13, wherein an upper end of each of the plurality of transfer gates is disposed beneath the floating diffusion region.

16. A method of manufacturing an image sensor comprising:
forming a photoelectric conversion region in a semiconductor substrate, wherein the photoelectric conversion region generates electric charges according to incident light;
forming a semiconductor projecting section that is projecting from the semiconductor substrate and extending upward above the photoelectric conversion region;
forming a floating diffusion region on a distal end side of the semiconductor projecting section; and
forming a transfer gate on the semiconductor substrate surrounding the semiconductor projecting section and isolated from the semiconductor projecting section.

17. The method according to claim 16, wherein the step of forming the semiconductor projecting section comprises epitaxially growth of a semiconductor layer on a surface of semiconductor substrate.

18. The method according to claim 17, wherein the step of forming a transfer gate on the semiconductor substrate surrounding the semiconductor projecting section comprises forming a plurality of equally spaced vertical transfer gates extending from the surface of semiconductor substrate into the semiconductor substrate.

19. The method according to claim 16, further comprising a thermally oxidizing process to form an insulating film on side surfaces of the semiconductor projecting section.
